(19) United States
(12) Patent Application Publication
(10) Pub. No.: US 2024/0345155 A1
(43) Pub. Date: Oct. 17, 2024

(54) TEST METHOD OF TEST SYSTEM AND TEST SYSTEM

(71) Applicant: Tokyo Electron Limited, Tokyo (JP)

(72) Inventor: Kenichi NARIKAWA, Tokyo (JP)

(21) Appl. No.: 18/579,659

(22) PCT Filed: Jul. 21, 2022
(86) PCT No.: PCT/JP2022/028363

§ 371 Date: Jan. 16, 2024

(30) Foreign Application Priority Data
Jul. 29, 2021 (JP) 2021-124355

(51) Int. Cl. G01R 31/28; G01R 19/165; G01R 21/133

(52) U.S. Cl. CPC G01R 31/2839; G01R 19/16533; G01R 21/133

(57) ABSTRACT

A test system includes a plurality of test units, each of which is configured to perform an electrical test of an object to be tested. In the test method, at least one of the following determination processes (a) to (c) is performed based on a detected total current. (a) compare the total current with a start current threshold value at a timing when an unoperated unit starts testing, and wait for a start of the testing of the unoperated unit when the total current is greater than or equal to the start current threshold value, (b) compare the total current with an in-operation current threshold value during testing of an operating unit, cause the operating unit to wait when the total current is greater than or equal to the in-operation current threshold value, and (c) compare the total current with a processing speed current threshold value at a timing when the unoperated unit starts testing, set a low-power and low-speed processing content to start the testing of the unoperated unit when the total current is greater than or equal to the processing speed current threshold value.

### TECHNICAL FIELD

The present disclosure relates to a test method of a test system and the test system.

### BACKGROUND

Patent Document 1 discloses a test system including multiple testers (test units) configured to perform electrical tests on objects to be tested. A factory including such a type of test system secures a power supply capacity based on the assumption that the power consumption of each test unit reaches maximum at the same time.

### RELATED ART DOCUMENT

### Patent Document

Patent Document 1: Japanese Laid-open Patent Application Publication No. 2019-29627

### SUMMARY OF THE INVENTION

### Problem to be Solved by the Invention

The present disclosure provides a technique capable of suppressing power consumption of a test system including multiple test units.

### Means for Solving Problem

According to an aspect of the present disclosure, there is provided a test method of a test system including a plurality of test units, each of which is configured to perform an electrical test of an object to be tested, the test method including detecting a total current that is a sum of a current supplied to each of the plurality of test units or a total power that is a sum of a power supplied to each of the plurality of test units; and performing at least one of following determination processes (a) to (c) based on the total current or the total power that is detected.

The determination process (a): compare the total current with a start current threshold value or compare the total power with a start power threshold value at a timing when an unoperated unit that is not performing testing among the plurality of test units starts the testing; wait for a start of the testing of the unoperated unit when the total current is greater than or equal to the start current threshold value or the total power is greater than or equal to the start power threshold value as a result of the comparison; and start the testing of the unoperated unit when the total current is less than the start current threshold value or the total power is less than the start power threshold value, the determination process (b): compare the total current with an in-operation current threshold value or compare the total power with an in-operation power threshold value during testing of an operating unit, the operating unit being performing the testing among the plurality of test units; cause at least one of the operating units to wait when the total current is greater than or equal to the in-operation current threshold value or the total power is greater than or equal to the in-operation power threshold value as a result of the comparison; and continue the testing of the operating unit when the total current is less than the in-operation current threshold value or the total power is less than the in-operation power threshold value, and the determination process (c): compare the total current with a processing speed current threshold value or compare the total power with a processing speed power threshold value at a timing when the unoperated unit starts testing; set a low-power and low-speed processing content to start the testing of the unoperated unit when the total current is greater than or equal to the processing speed current threshold value or the total power is greater than or equal to the processing speed power threshold value as a result of the comparison; and set a high-power and high-speed processing content to start the testing of the unoperated unit when the total current is less than the processing speed current threshold value or the total power is less than the processing speed power threshold value.

### Effect of the Invention

According to one embodiment, power consumption of a test system including multiple test units can be suppressed.

### BRIEF DESCRIPTION OF THE DRAWINGS

FIG. 1 is a diagram illustrating an overall configuration of a test system according to an embodiment.

FIG. 2 is a schematic cross-sectional view along a horizontal direction of a test device.

FIG. 3 is a schematic cross-sectional view along a vertical direction of a transfer region and a test region.

FIG. 4 is a schematic vertical cross-sectional view illustrating a test unit including a tester and a probe card.

FIG. 5 is a block diagram illustrating an electrical connection and a communication connection of hardware of the test device.

FIG. 6 is a block diagram illustrating functional units of a controller.

FIG. 7 is a diagram illustrating a determination process of a first determination processing unit with respect to a total current.

FIG. 8 is a diagram illustrating a determination process of a second determination processing unit with respect to the total current.

FIG. 9 is a diagram illustrating a determination process of a third determination processing unit with respect to the total current.

FIG. 10 is an explanatory diagram illustrating examples of a start current threshold, a release current threshold, an in-operation current threshold, a restart current threshold, and a processing speed current threshold.

FIG. 11 is a flowchart illustrating a test method at a start of testing of an unoperated unit.

FIG. 12 is a flowchart illustrating a test method during an operation of an operating unit.

FIG. 13 is a block diagram illustrating an electrical connection and a communication connection of hardware of a test device according to a modified example.

FIG. 14 is a block diagram illustrating a test system according to another modified example.

### DESCRIPTION OF EMBODIMENTS

In the following, embodiments of the present disclosure will be described with reference to the drawings. In the drawings, the same components are denoted by the same reference symbols, and duplicated description may be omitted.

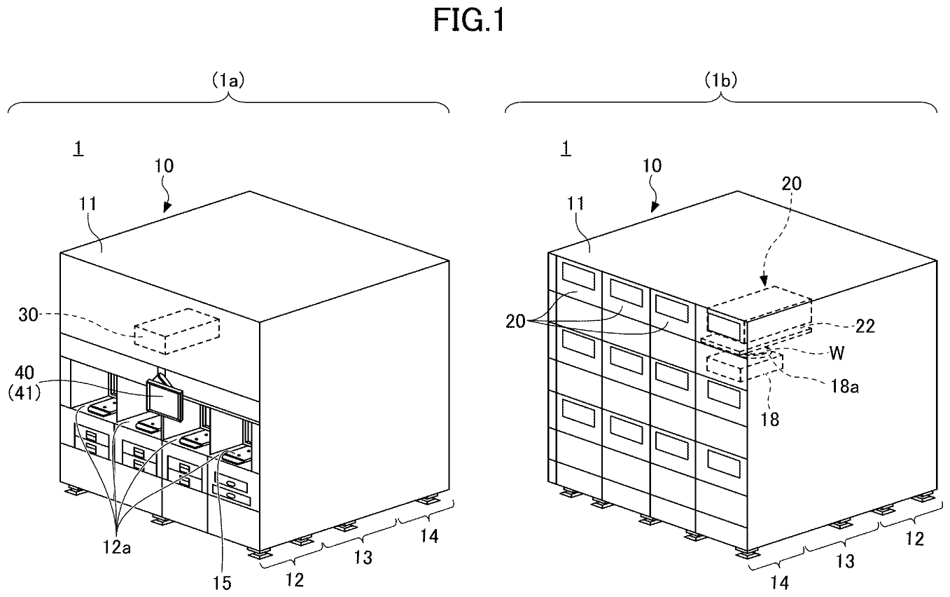

FIG. 1 is a diagram illustrating an overall configuration of a test system 1 according to an embodiment of the present disclosure, (1a) is a perspective view from a carry-in/out region 12, and (1b) is a perspective view from a test region 14. As illustrated in FIG. 1, the test system 1 according to the embodiment includes one or more (one in the illustrated example) test devices 10 configured to test a wafer W (an object to be tested), which is an example of a substrate. A test device 10 is installed in, for example, a clean room of a factory that manufactures wafers W or the like.

The test device 10 includes a rectangular housing 11, and multiple testers 20 configured to electrically test wafers W in the housing 11. Additionally, the test device 10 includes, in the housing 11, a controller 30 (a control unit) configured to control the operation of the test device 10 and an operation terminal 40 used for an operation of a user of the test device 10.

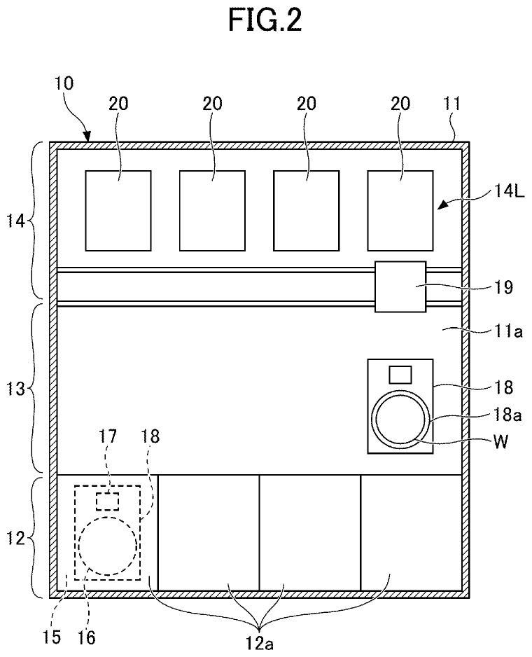

FIG. 2 is a schematic cross-sectional view along the horizontal direction of the test device 10. As illustrated in FIG. 2, the housing 11 includes the carry-in/out region 12 in which the wafer W is carried in and out between the outside and the inside (a test chamber 11a) of the housing 11, a transfer region 13 in which the wafer W in the carry-in/out region 12 is transferred, and the test region 14 in which the wafer W transferred from the transfer region 13 is tested.

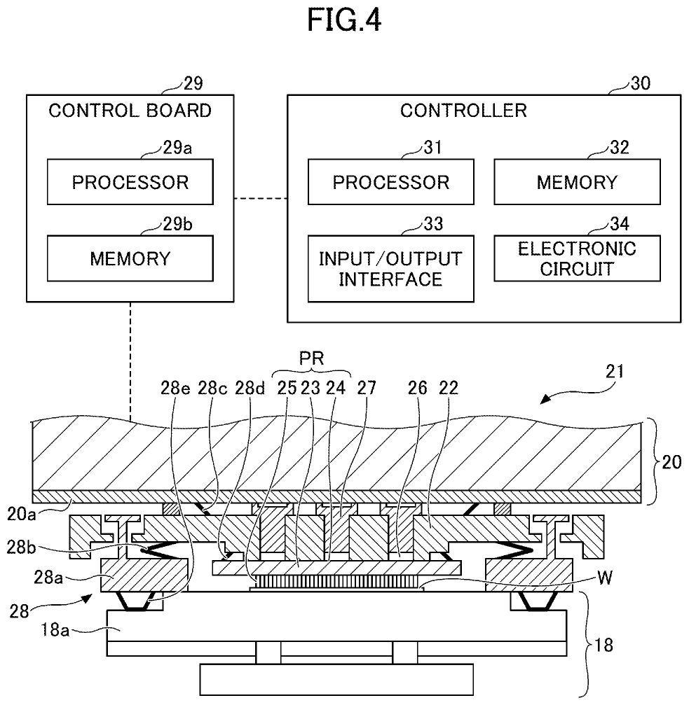

In the carry-in/out region 12, multiple carry-in/out sections 12a are provided along the horizontal direction of the housing 11 (see also FIG. 1). Each carry-in/out section 12a includes a load port 15, an aligner 16, and the like. The load port 15 receives a FOUP, which is a container for accommodating multiple wafers W. The aligner 16 aligns the position of the wafer W. Additionally, the carry-in/out region 12 incudes a loader 17 for carrying in and out a probe card PR (see FIG. 4) used in each of the multiple testers 20.

The transfer region 13 includes multiple transfer stages 18 that are movable to the carry-in/out region 12 and the test region 14. One transfer stage 18 is provided for each tester line 14L of the test region 14, which will be described later. The transfer stage 18 receives the wafer W from the load port 15 of the carry-in/out region 12, transfers the wafer W to the test region 14, and transfers the tested wafer W from the test region 14 to the load port 15. Additionally, when the probe card PR of the tester 20 is replaced, the transfer stage 18 receives the probe card PR from the test region 14 and transfers the probe card PR to the loader 17, and transfers a new probe card PR from the loader 17 to the test region 14.

The transfer stage 18 has a chuck device 18a that positions and fixes the wafer W on the upper surface thereof by vacuum suction. Here, the method of holding the chuck device 18a is not limited to vacuum suction, but may be, for example, electromagnetic suction or clamping.

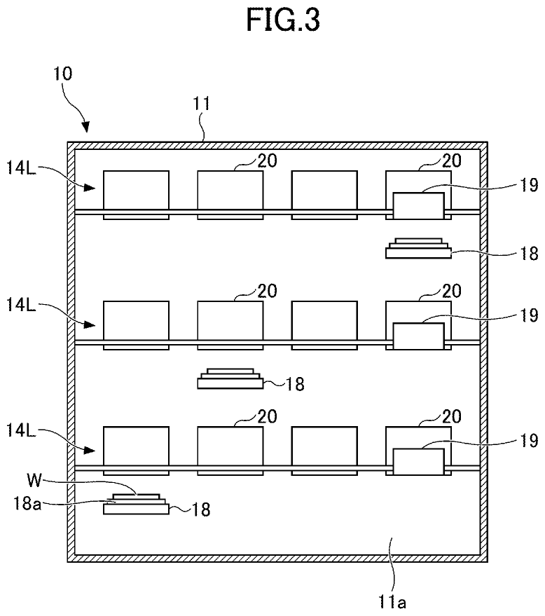

FIG. 3 is a schematic cross-sectional view along the vertical direction of the transfer region 13 and the test region 14. As illustrated in FIG. 3, the test region 14 includes multiple testers 20 configured to test the wafers W. Specifically, the multiple testers 20 are arranged in the horizontal direction and the vertical direction (in the height direction) in a matrix (see also the drawing (1b)). Hereinafter, a group of the multiple testers 20 arranged in the horizontal direction is referred to as the tester line 14L. The tester line 14L includes four testers 20 in the horizontal direction, and the test device 10 includes three stages (multiple stages) of the tester lines 14L in the vertical direction. That is, the test device 10 includes twelve testers 20. Here, it is needless to say that the number of the testers 20 constituting the tester line 14L and the number of stages of the tester lines 14L in the test device 10 are not particularly limited.

Additionally, the test region 14 includes one camera 19 for each of the multiple tester lines 14L. Each camera 19 moves horizontally along the corresponding tester line 14L and captures an image of the position and the like of the wafer W transferred by the transfer stage 18 in front of each tester 20 included in the tester line 14L.

FIG. 4 is a schematic vertical cross-sectional view illustrating a test unit 21 including the tester 20 and the probe card PR. As illustrated in FIG. 4, each tester 20 in the test region 14 includes a pogo frame 22 (a test head) on which the probe card PR is mounted, and performs an electrical test of the wafer W in a state where the probe card PR is mounted. That is, in the test of the wafer W, the test device 10 forms the test unit 21 by assembling the tester 20 and the probe card PR.

A main part of each tester 20 is mounted above the pogo frame 22 connected to a frame in the housing 11 via a base 20a. Additionally, the probe card PR is mounted to a lower portion of the pogo frame 22.

The probe card PR includes a disk-shaped main body 23, a large number of electrodes 24 arranged on an upper surface of the main body 23, and a large number of contact probes 25 (contact terminals) connected to the electrodes 24 and protruding downward from a lower surface of the main body 23. Each contact probe 25 contacts the wafer W to come into electrical contact with an electrode pad or a solder bump of a semiconductor device formed on the wafer W. The contact probes 25 collectively come into contact with the entire surface of the wafer W, so that the electrical characteristics of a large number of semiconductor devices can be tested simultaneously, for example.

The pogo frame 22 is formed in a substantially flat plate shape and has multiple through-holes 26 in the vicinity of a central portion thereof. A pogo block 27 including a large number of pogo pins is inserted into each through-hole 26. The pogo block 27 is connected to a test circuit of the main part of the tester 20, and can be brought into contact with a large number of electrodes 24 of the probe card PR.

Additionally, the pogo frame 22 has a vacuum mechanism 28 configured to form a vacuum between the pogo frame 22 and the transfer stage 18. The vacuum mechanism 28 includes a flange 28a engaged with the pogo frame 22 so as to be movable up and down, a bellows 28b surrounding a space between the pogo frame 22 and the flange 28a, and seal members 28c and 28d surrounding a space between the pogo frame 22, the base 20a, and the probe card PR. Additionally, a contact member 28e that can be in airtight contact with the chuck device 18a is provided on a lower end surface of the flange 28a. The vacuum mechanism 28 mounts the base 20a to the pogo frame 22 and mounts the chuck device 18a and the probe card PR to the pogo frame 22 by vacuuming the space surrounded by the seal member 28c using a vacuum pump, which is not illustrated.

Each tester 20 includes a control board 29 operating each component inside the tester 20. The control board 29 is a tester computer built-in board including one or more processors 29a, a memory 29b, an input/output interface, an electronic circuit, and the like, which are not illustrated. The one or more processors 29a are a combination of one or more CPUs, ASICS, FPGAs, circuits including multiple discrete semiconductors, and the like, and execute and process programs and recipes stored in the memory 29b. The memory 29b includes a nonvolatile memory and a volatile memory, and forms a storage unit of the control board 29.

The processor 29a of the control board 29 executes an appropriate program or recipe in response to a control command transmitted from the controller 30 to operate each component, to perform an electrical test on the wafer w. Additionally, the processor 29a transmits a test result of the wafer W to the controller 30.

With respect to the above, the controller 30 of the test device 10 includes a computer for controlling the entire test device 10 including one or more processors 31, a memory 32, an input/output interface 33, and an electronic circuit 34. The one or more processors 31 are a combination of one or more of CPUs, ASICS, FPGAS, circuits including multiple discrete semiconductors, and the like, and execute a program stored in the memory 32. The memory 32 includes a nonvolatile memory and a volatile memory, and forms a storage unit of the controller 30.

The controller 30 is communicably connected to the load port 15, the aligner 16, the loader 17, the transfer stage 18, the camera 19, the tester 20 (see FIG. 2), and the like via the input/output interface 33.

Additionally, the controller 30 is connected to an operation terminal 40 provided on the housing 11 of the test device 10 via the input/output interface 33 (see FIG. 1). The operation terminal 40 includes a touch panel 41 and the like constituting an input/output device of the test device 10. Here, the operation terminal 40 is not particularly limited and a monitor, a speaker, a keyboard, a mouse, or the like may be applied. The controller 30 receives a test content of the test device 10 that is input by a user through the operation terminal 40, outputs a control command to each component of the test device 10 based on the test content, and performs an electrical test on the wafer W. Additionally, when receiving a test result from each tester 20, the controller 30 stores the test result in the memory 32 and displays the test result via the operation terminal 40 under the operation of the user.

As illustrated in FIG. 1 to FIG. 4, the test device 10 holds the wafer W in the carry-in/out region 12 by the transfer stage 18 and moves the transfer stage 18 based on the control of the controller 30. This causes the test device 10 to transfer the wafer W below the probe card PR of the tester 20 and brings the wafer W closer to the probe card PR. When the transfer stage 18 comes into contact with the flange 28a, a space surrounded by the probe card PR, the transfer stage 18, the pogo frame 22, and the flange 28a is formed below the probe card PR.

When receiving the control command of the test device 10, the control board 29 of the tester 20 operates the vacuum mechanism 28 to vacuum the space sealed by the bellows 28b, so that the chuck device 18a is held on the pogo frame 22. At this time, each electrode pad or each solder bump in each semiconductor device of the wafer W comes into contact with a corresponding contact probe 25 of the probe card PR.

With this, each test unit 21 (the tester 20 and the probe card PR) supplies a current to the electronic circuit of each semiconductor device of the wafer W via the pogo pin and a corresponding contact probe 25 of the probe card PR based on the control of the control board 29. Then, the control board 29 electrically tests the current returning from the wafer W via each contact probe 25 and the pogo pin in the test circuit.

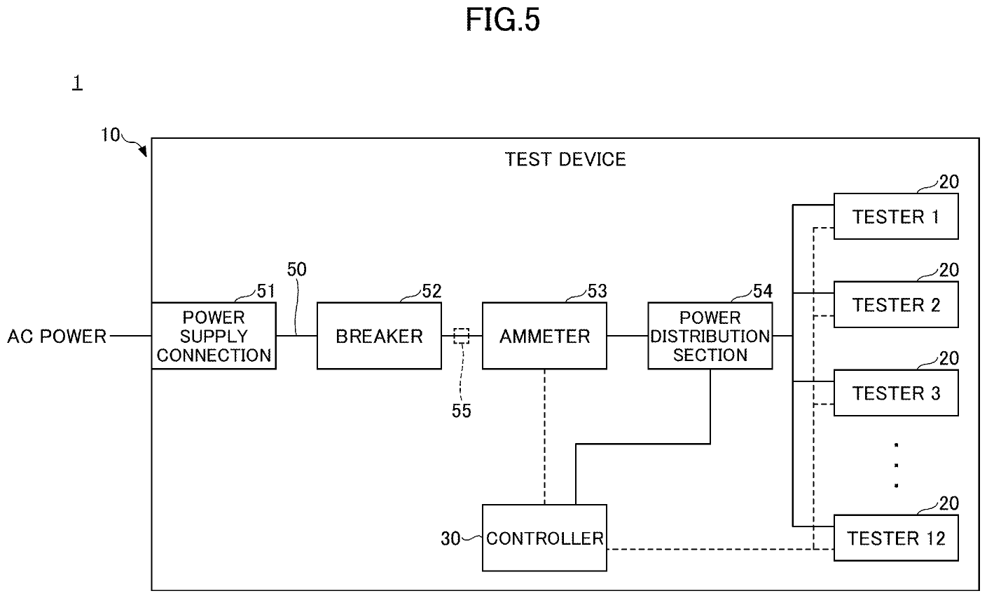

FIG. 5 is a block diagram illustrating an electrical connection and a communication connection of hardware of the test device 10. As illustrated in FIG. 5, the test device 10 includes an electric wiring 50 that connects the components of the test device 10. Additionally, the test device 10 includes, as the components of an electric system connected via the electric wiring 50, a power supply connection 51, a breaker 52 connected in series to the power supply connection 51, an ammeter 53 connected in series to the breaker 52, and a power distribution section 54 connected in series to the ammeter 53. The multiple testers 20 (test units 21) and the controller 30 are connected in parallel to the power distribution section 54, and are supplied with power distributed by the power distribution section 54.

Additionally, the test device 10 includes, as a communication system, an appropriate communication method (see a dotted line in FIG. 5) that connects each tester 20 to the controller 30 and the ammeter 53 to the controller 30 so that information can be communicated. The communication method is not particularly limited, and either wired or wireless communication may be applied.

The power supply connection 51 of the test device 10 is connected to an AC power supply supplying power to a factory. The AC power supply supplies, for example, an alternating voltage of 200 V to the test device 10. The power supply connection 51 may include an adapter that converts AC power into DC power.

The breaker 52 restricts a supply of an overcurrent to the test device 10 by cutting off the electric wiring 50 when the current supplied to the test device 10 is greater than or equal to a predetermined breaking current value (the rated current). The breaking current value of the breaker 52 is not particularly limited, but may be set to, for example, 70% or less of the current that can be supplied to the factory (a breaker of the factory).

The ammeter 53 detects a total current that is a sum of currents supplied to the respective testers 20, and outputs a detection signal (information on the total current) to the controller 30. Here, the installation position of the ammeter 53 is not particularly limited as long as the installation position is closer to the power supply connection 51 than the power distribution section 54, and may be between the power supply connection 51 and the breaker 52.

The power distribution section 54 supplies power required for the operation of the controller 30 and supplies power to each tester 20 in accordance with the operation state of each test unit 21. Additionally, the power distribution section 54 supplies appropriate power to other components of the test device 10 (the load port 15, the aligner 16, the loader 17, the transfer stage 18, the camera 19, and the like: see FIG. 2). Here, the test device 10 according to the present embodiment is configured such that the controller 30 is connected to the power distribution section 54 on the downstream side of the ammeter 53, but may be configured such that the power distribution section 55 is provided on the upstream side of the ammeter 53 as indicated by a dotted line in FIG. 5, and the controller 30 is connected to the power distribution section 55.

The controller 30 is activated based on the power supplied from the power supply system of the test device 10 and performs the above-described electrical test of the wafer W. At this time, the controller 30 adjusts a progress of the testing of each test unit 21 based on the total current supplied to each tester 20 (test unit 21) acquired from the ammeter 53 to suppress the power consumption (the current consumption) of the entire test device 10.

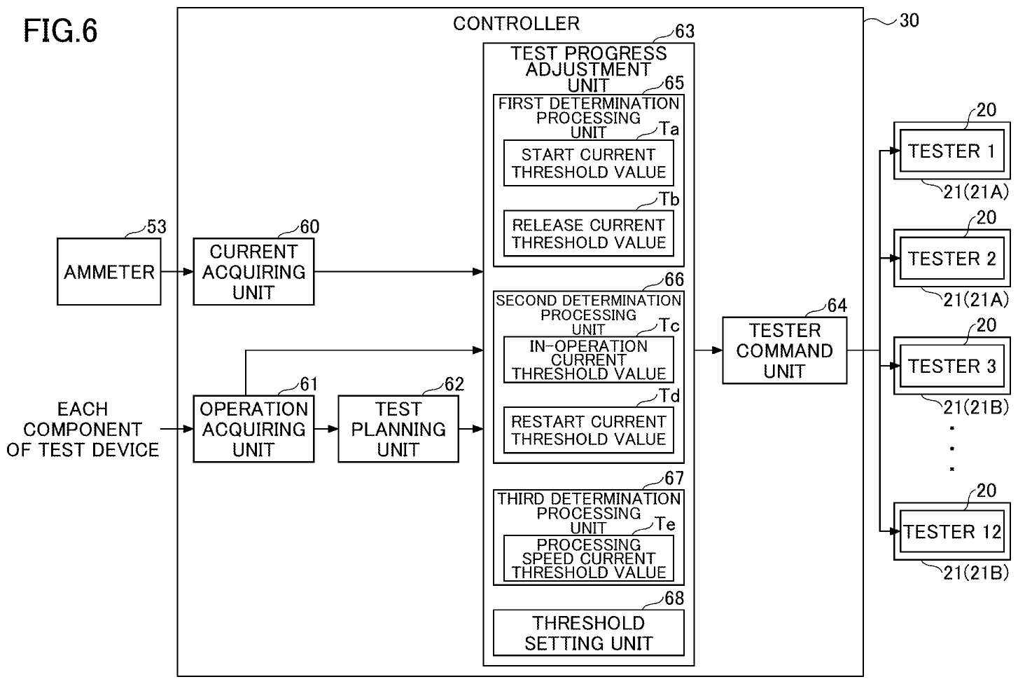

FIG. 6 is a block diagram illustrating functional units of the controller 30. The processor 31 executes the program stored in the memory 32 to form the functional blocks for suppressing the power consumption as illustrated in FIG. 6. In detail, a current acquiring unit 60, an operation acquiring unit 61, a test planning unit 62, a test progress adjusting unit 63, and a tester command unit 64 are formed inside the controller 30.

The current acquiring unit 60 acquires information on the total current detected by the ammeter 53, temporarily stores the information in the memory 32, and outputs the information to the test progress adjusting unit 63.

The operation acquiring unit 61 continuously acquires information on an operation state from each component (the load port 15, the transfer stage 18, the multiple testers 20, and the like) of the test device 10. For example, examples of the operation state of the test unit 21 include identification information of the test unit 21, an in-operation state of the electrical test or a non-operation state of the electrical test, a test item in a case where the electrical test is in operation, a program used in the electrical test, and the like.

Based on the information from the operation acquiring unit 61, the test planning unit 62 recognizes an operating unit 21A that is currently performing testing among the multiple test units 21 (testers 20) and an unoperated unit 21B that is not performing testing among the multiple test units 21. At this time, it is preferable that the test planning unit 62 refers to a test item currently performed by the operating unit 21A and recognizes the progress of the testing. Then, the test planning unit 62 plans the testing of the unoperated unit 21B based on the usable transfer stage 18, the number of wafers W to be tested, and the like. For example, when the wafer W to be tested is present in the load port 15 and an unused transfer stage 18 is present, the test planning unit 62 determines the operation of the unoperated unit 21B among the test units 21 of the tester line 14L where the transfer stage 18 is present. Then, the test planning unit 62 outputs plan information for starting the testing of the unoperated unit 21B to the test progress adjusting unit 63.

The test progress adjusting unit 63 performs a determination process of adjusting the testing of each test unit 21 based on the information on the total current of the current acquiring unit 60, the information on the operation state of each component of the operation acquiring unit 61, and the plan information of the test planning unit 62. Specifically, the test progress adjusting unit 63 sets the following determinations (a) to (c) and processing contents according to the determinations.

(a) When the total current is small, the start of the testing of the unoperated unit 21B is permitted, and when the total current is large, the start of the testing of the unoperated unit 21B is on standby until the total current becomes small.

(b) When the total current is small, the testing of the operating unit 21A is continued, and when the total current is large, the testing of the operating unit 21A is temporarily on standby until the total current becomes small.

(c) When the total current is small, the testing of the unoperated unit 21B is started so as to perform the test at a high throughput, and when the total current is large, the testing of the unoperated unit 21B is started so as to perform the test at a low throughput.

In order to perform the above-described processes (a) to (c), a first determination processing unit 65, a second determination processing unit 66, and a third determination processing unit 67 are formed in the test progress adjusting unit 63. Furthermore, it is preferable that a threshold value setting unit 68 is formed in the test progress adjusting unit 63 so that the user can set each current threshold value to be compared with the total current.

The first determination processing unit 65 performs the determination (a) and the setting of the processing content based on the instruction to start the testing of the unoperated unit 21B in the plan information of the test planning unit 62. Thus, the first determination processing unit 65 includes a start current threshold value Ta to be compared with the total current. The start current threshold value Ta is not particularly limited, but may be set in a range of about 50% to 70% relative to the breaking current value of the breaker 52. The first determination processing unit 65 determines to wait for the start of the testing of the unoperated unit 21B when the total current is greater than or equal to the start current threshold value Ta, and determines to start the testing of the unoperated unit 21B when the total current is less than the start current threshold value Ta.

Further, when waiting for the start of the testing of the unoperated unit 21B, the first determination processing unit 65 measures the timing of transition from the wait state to the testing. Thus, the first determination processing unit 65 includes a release current threshold value Tb to be compared with the total current. The release current threshold value Tb is a current value less than or equal to the start current threshold value Ta, and may be set, for example, in a range of about 40% to 60% relative to the breaking current value of the breaker 52. The first determination processing unit 65 determines to continue the wait of the unoperated unit 21B when the total current is greater than or equal to the release current threshold value Tb, and determines to start the testing of the unoperated unit 21B when the total current is less than the release current threshold value Tb.

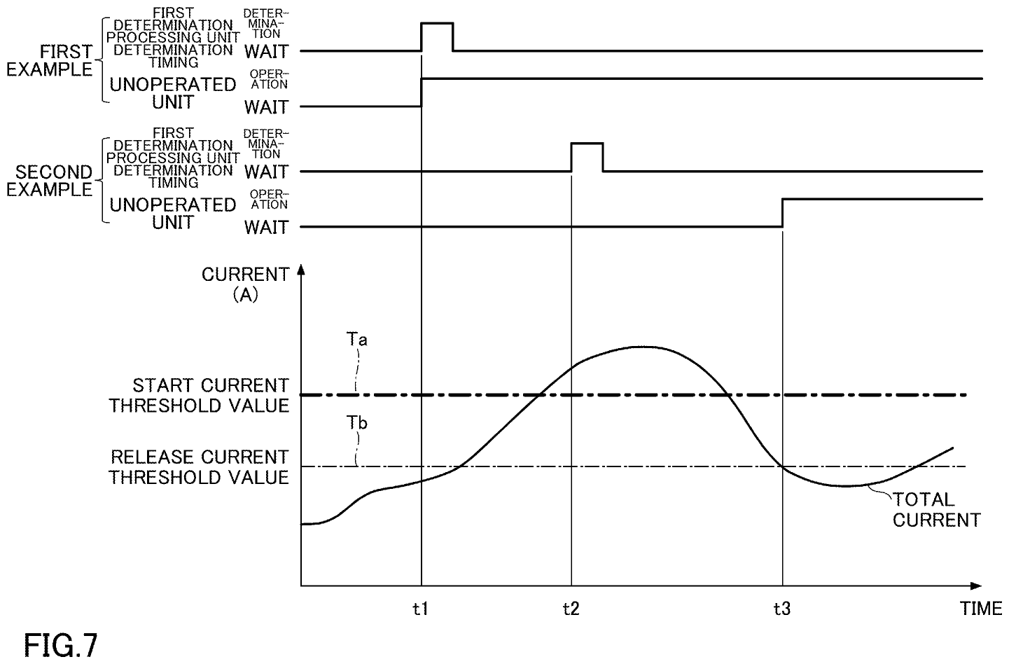

FIG. 7 is a diagram depicting the determination process of the first determination processing unit 65 with respect to the total current. Specifically, the first determination processing unit 65 compares the total current detected by the ammeter 53 with the start current threshold value Ta based on the reception of the test start instruction at a timing (a time point t1) of a first example illustrated in FIG. 7. Because the total current is less than the start current threshold value Ta at the time point t1, the first determination processing unit 65 immediately starts the testing of the unoperated unit 21B at the time point t1.

At a timing (a time point t2) of a second example illustrated in FIG. 7, the total current is greater than or equal to the start current threshold value Ta. When the test start instruction is received at this timing, the first determination processing unit 65 waits for the start of the testing of the unoperated unit 21B. When waiting for the start of the testing, the test device 10 may perform the operation of the transfer stage 18 to the unoperated unit 21B that is a standby target or may stop the operation itself of the transfer stage 18. By performing the operation of the transfer stage 18, the test device 10 can smoothly start the testing of the unoperated unit 21B after waiting. When the operation of the transfer stage 18 is stopped, the test device 10 can more easily reduce the total current.

When waiting for the start of the testing, the first determination processing unit 65 further monitors a timing (a time point t3) when the total current becomes less than the release current threshold value Tb, and determines the start of the testing of the unoperated unit 21B at the time point t3.

Here, when there is the unoperated unit 21B that has been determined to wait for the start of the test earlier, even if receiving the plan information for starting the testing of the next unoperated unit 21B, the first determination processing unit 65 preferably waits for the determination of the next unoperated unit 21B. This allows the test device 10 to prevent the order of the unoperated units 21B performing the test from being exchanged.

Returning to FIG. 6, the second determination processing unit 66 performs the determination (b) and the setting of the processing content during the testing of the operating unit 21A based on the operation state of the test unit 21 of the operation acquiring unit 61. Thus, the second determination processing unit 66 includes an in-operation current threshold value Tc to be compared with the total current. The in-operation current threshold value Tc is also not particularly limited, and may be set, for example, in a range of about 70% to 90% relative to the breaking current value of the breaker 52. The second determination processing unit 66 causes at least one of the operating units 21A to wait when the total current is greater than or equal to the in-operation current threshold value Tc, and continues the testing of the operating unit 21A when the total current is less than the in-operation current threshold value Tc.

With respect to the operating unit 21A being caused to wait, regarding multiple test items scheduled to be performed in the testing, it is preferable that a test whose test item is already being performed is continued, and at the timing when the test item is finished, the operating unit 21A is caused to wait without performing the next test item. This allows the test device 10 to avoid performing the test item that is already being performed again.

Further, when the testing of the operating unit 21A is on standby, the second determination processing unit 66 waits for the timing to restart the test from the wait state. Thus, the second determination processing unit 66 includes a restart current threshold value Td to be compared with the total current. The restart current threshold value Td is a current value less than or equal to the in-operation current threshold value Tc, and may be set to, for example, a range of about 60% to 80% relative to the breaking current value of the breaker 52. The second determination processing unit 66 determines to continue the wait of the operating unit 21A when the total current is greater than or equal to the restart current threshold value Td, and determines to restart the testing of the operating unit 21A when the total current reaches a value less than the restart current threshold value Td.

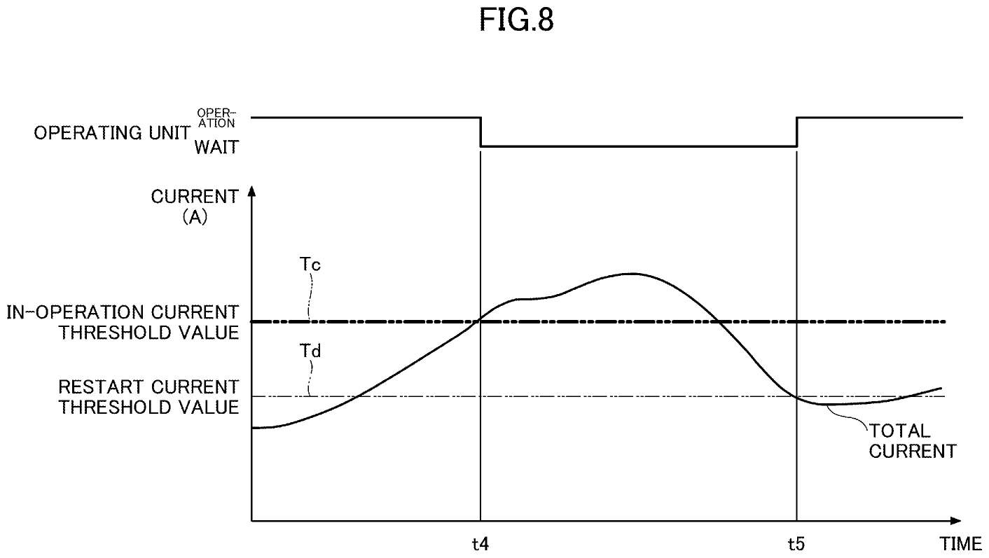

FIG. 8 is a diagram depicting the determination process of the second determination processing unit 66 with respect to the total current. Specifically, as illustrated in FIG. 8, the second determination processing unit 66 continuously repeats the comparison between the in-operation current threshold value Tc and the total current during the testing of the operating unit 21A. Then, at a timing (a time point t4) when the total current becomes greater than or equal to the in-operation current threshold value Tc, the second determination processing unit 66 determines the wait of the operating unit 21A. Here, at this time, the operating unit 21A continues the test item that is already being performed and waits thereafter, so that the total current may increase even after the time point t4.

When the operating unit 21A enters the wait state, the total current of the test device 10 decreases. Also at this time, the second determination processing unit 66 continues to monitor the total current and continuously repeats the comparison between the restart current threshold value Td and the total current. The second determination processing unit 66 continues the monitoring until the total current becomes less than the restart current threshold value Td, and when the total current becomes less than the restart current threshold value Td at a time point t5, the second determination processing unit 66 restarts the testing of the operating unit 21A that has been caused to wait.

Here, when determining the wait of the operating unit 21A during the testing of multiple operating units 21A, it is preferable that the second determination processing unit 66 causes each of the multiple operating units 21A to wait with a time interval. For example, the second determination processing unit 66 compares the in-operation current threshold value Tc with the total current after a predetermined period of time has elapsed with respect to the operating unit 21A that has been caused to wait first, and determines whether the total current decreases, thereby determining whether another operating unit 21A is caused to wait next. This can prevent the test of the wafer W from being delayed due to multiple operating units 21A waiting continuously or simultaneously.

Additionally, in the wait of the operating unit 21A, priority may be given to causing the operating unit 21A having a smaller number of test items that have been already performed (operated later) among the multiple operating units 21A to wait. This can end earlier the testing of the operating unit 21A having a larger number of test items that have been already performed (operated earlier), and the operation of the operating unit 21A that is on standby can be restarted. For example, when the test is performed by each of the test units 21 of the same tester line 14L, the efficiency including the transfer of the wafer W can be improved by performing the testing of the operating unit 21A operated earlier.

Conversely, in the wait of the operating unit 21A, the operation of the operating unit 21A having a larger number of test items that have been already performed among the plurality of operating units 21A may be on standby. This can advance the testing of the operating unit 21A operated later to reduce the time lag with the operating unit 21A operated earlier. For example, when the test is performed by each of the test units 21 of the different tester lines 14L, the efficiency of the test can be improved by reducing the time lag.

Returning to FIG. 6, the third determination processing unit 67 performs the determination (c) and the setting of the processing content at the timing when the unoperated unit 21B starts the test based on the plan information of the test planning unit 62. Thus, the third determination processing unit 67 includes a processing speed current threshold value Te to be compared with the total current. When the total current is greater than or equal to the processing speed current threshold value Te, the third determination processing unit 67 determines that the testing of the unoperated unit 21B is performed with a processing content of a low power (a low current) and a low speed (a low throughput) being set. Additionally, when the total current is less than the processing speed current threshold value Te, the third determination processing unit 67 determines that the testing of the unoperated unit 21B is performed with a processing content of a high power (a high current) and a high speed (a high throughput) being set.

The processing speed current threshold value Te may be set to a current value less than or equal to the start current threshold value Ta. If the processing speed current threshold value Te exceeds the start current threshold value Ta, even though the total current exceeds the start current threshold value Ta at the start of the unoperated unit 21B and the unoperated unit 21B enters the wait state, the test is performed with a high-throughput program at the start of the test after the wait state. That is, there is no opportunity to select a low-throughput program. As an example, the processing speed current threshold value Te may be set in a range of about 30% to 50% relative to the breaking current value of the breaker 52.

For example, the control boards 29 of the multiple testers 20 include, in advance, a low-throughput program for low-power and low-speed testing and a high-throughput program for high-power and high-speed testing. The low-throughput program is a program for suppressing a current flowing through the wafer W by limiting the contact probes 25 through which the current flows among the multiple contact probes 25. With this, although the testing of the test unit 21 is delayed, the test can be performed with reduced power consumption. The high-throughput program is a program for increasing the amount of the current flowing through the wafer W by increasing the number of contact probes 25 through which the current flows among the multiple contact probes 25. This increases the power consumption of the test unit 21, but shortens the test time because the test becomes faster. The control board 29 receives a program selection command together with an operation start command from the controller 30, and thereby executes either the low-throughput program or the high-throughput program to perform the testing.

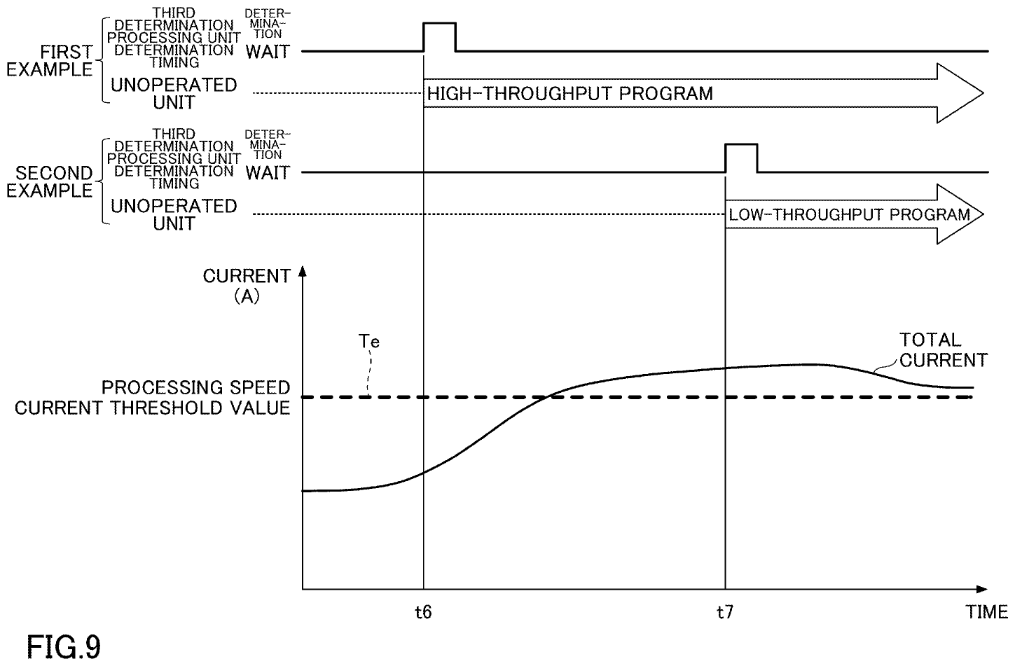

FIG. 9 is a diagram depicting the determination process of the third determination processing unit 67 with respect to the total current. Specifically, the third determination processing unit 67 compares the total current detected by the ammeter 53 with the processing speed current threshold value Te based on the reception of the test start instruction at a timing (a time point t6) of a first example illustrated in FIG. 9. At the time point t6, because the total current is less than the processing speed current threshold value Te, the third determination processing unit 67 determines the execution of the high-throughput program for the unoperated unit 21B.

At a timing (a time point t7) of a second example illustrated in FIG. 9, the total current is greater than or equal to the processing speed current threshold value Te. When the test start instruction is received at this timing, the third determination processing unit 67 determines the execution of the low-throughput program for the unoperated unit 21B. With this, even when the testing of the unoperated unit 21B is started, the amount of current of the unoperated unit 21B added to the total current is small.

Here, when the determination by the first determination processing unit 65 and the determination by the third determination processing unit 67 are performed at the start of the testing of the unoperated unit 21B, it is preferable that the test progress adjusting unit 63 holds both determination results until the testing of the unoperated unit 21B is started. For example, when the first determination processing unit 65 determines to wait for the start of the testing of the unoperated unit 21B, the third determination processing unit 67 determines to use the low-throughput program. By holding the determination result of the third determination processing unit 67, when the first determination processing unit 65 determines that the total current is less than the release current threshold value Tb, the testing of the unoperated unit 21B can be performed by the low-throughput program.

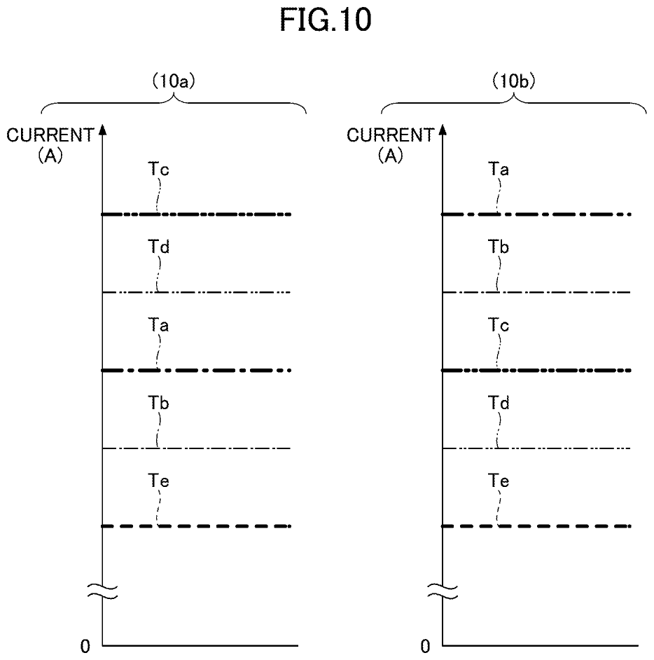

FIG. 10 is an explanatory diagram illustrating examples of the start current threshold value Ta, the release current threshold value Tb, the in-operation current threshold value Tc, the restart current threshold value Td, and the processing speed current threshold value Te, and (10a) is a first embodiment and (10b) is a second embodiment. As illustrated in (10a), the controller 30 sets the respective current thresholds in accordance with the total current in stages. Specifically, the processing speed current threshold value Te<the start current threshold value Ta<the in-operation current threshold value Tc. This allows the test device 10 to preferentially test the wafer W that is being tested while reducing the number of test units 21 that perform the testing. Here, in (10a), the release current threshold value Tb is set between the processing speed current threshold value Te and the start current threshold value Ta, but the release current threshold value Tb may be lower than the processing speed current threshold value Te as long as the release current threshold value Tb is lower than or equal to the start current threshold value Ta. Additionally, in (10a), although the restart current threshold value Td is set between the start current threshold value Ta and the in-operation current threshold value Tc, the restart current threshold value Td may be lower than the start current threshold value Ta as long as the restart current threshold value Td is less than or equal to the in-operation current threshold value Tc.

Alternatively, the respective current threshold values may have an appropriate relationship in accordance with the test content of the wafer W, a user's request, and the like. For example, as illustrated in (10b), the controller 30 may set the processing speed current threshold value Te<the in-operation current threshold value Tc<the start current threshold value Ta. This allows the test device 10 to test multiple wafers W at the same time by increasing the number of test units 21 that perform the testing. Even when a large number of test units 21 perform the testing, the power consumption of the test device 10 can be suppressed while appropriately adjusting the test speed based on the processing speed current threshold value Te and the in-operation current threshold value Tc. Here, the in-operation current threshold value Tc may be set to be less than or equal to the processing speed current threshold value Te.

The requirements for the magnitude of each current threshold value described above are summarized as the following [1] to [3].

[1] The start current threshold value Ta and the in-operation current threshold value Tc can be suitably set.

[2] The release current threshold value Tb≤the start current threshold value Ta, and the restart current threshold value Td≤the in-operation current threshold value Tc

[3] The processing speed current threshold value Te≤the start current threshold value Ta

Returning to FIG. 6, the threshold value setting unit 68 is a functional unit that allows the user to set the respective current threshold values (the start current threshold value Ta, the release current threshold value Tb, the in-operation current threshold value Tc, the restart current threshold value Td, and the processing speed current threshold value Te) to be compared with the total current described above. For example, the threshold value setting unit 68 displays image information for setting the respective current threshold values on the operation terminal 40 (see the drawing (1a)), and changes the respective current threshold values according to the user's operation. Here, the threshold value setting unit 68 may automatically set the release current threshold value Tb when the start current threshold value Ta is set by the user. Similarly, the threshold value setting unit 68 may automatically set the restart current threshold value Td when the in-operation current threshold value Tc is set by the user.

The tester command unit 64 outputs a command to each tester 20 (test unit 21) based on the processing content set by the test progress adjusting unit 63. For example, when starting the operation of the unoperated unit 21B, the tester command unit 64 transmits a program selection command together with an operation start command to the unoperated unit 21B. The unoperated unit 21B that has received this command executes either the low-throughput program or the high-throughput program to start the testing. Here, when waiting for the operation of the unoperated unit 21B, the controller 30 continues the wait of the unoperated unit 21B by not transmitting the operation start command.

Additionally, for example, the tester command unit 64 outputs an in-operation wait command to the operating unit 21A when the operation of the operating unit 21A is caused to wait. The operating unit 21A that has received this command suspends the next test item and waits until after the test item that is already being executed is finished. Subsequently, the tester command unit 64 outputs an operation restart command to the operating unit 21A that is waiting, so that the operating unit 21A restarts the test from the next test item.

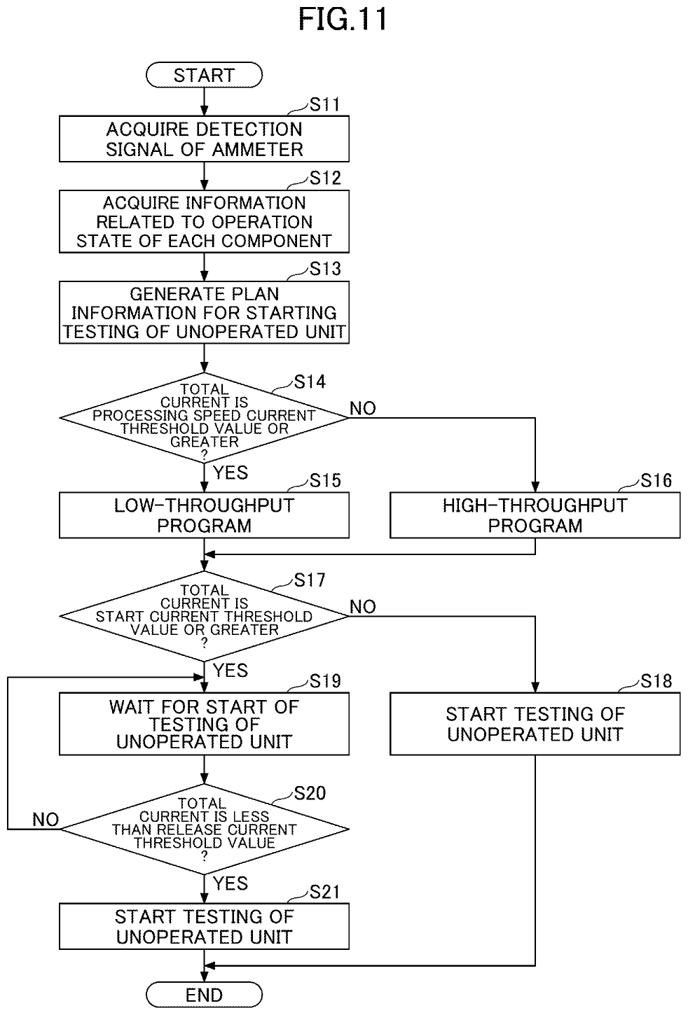

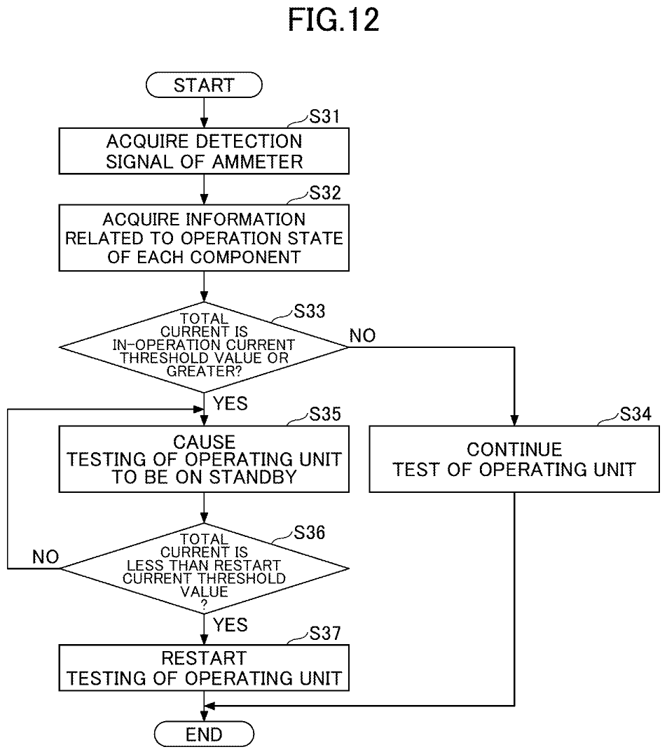

The test system 1 (the test device 10) according to the present embodiment is basically configured as described above, and the operation and effects thereof will be described below. FIG. 11 is a flowchart illustrating a test method at the start of the testing of the unoperated unit 21B. FIG. 12 is a flow chart illustrating a test method during the operation of the operating unit 21A.

As illustrated in FIG. 11, during the test of the wafer W by the operating unit 21A, the controller 30 of the test device 10 continuously acquires the detection signal (the information on the total current) of the ammeter 53 by the current acquiring unit 60 (step S11). Further, the controller 30 continuously acquires the information on the operation state of each component including the tester 20 by the operation acquiring unit 61 (step S12).

The test planning unit 62 generates the plan information for starting the testing of the unoperated unit 21B in accordance with the operation state of the test unit 21 (step S13).

When recognizing the start of the testing of the unoperated unit 21B based on the plan information, the test progress adjusting unit 63 performs the determination process by the first determination processing unit 65 and the third determination processing unit 67. Specifically, the third determination processing unit 67 determines whether the total current is greater than or equal to the processing speed current threshold value Te (step S14). If the total current is greater than or equal to the processing speed current threshold value Te (step S14: Yes), the tester command unit 64 commands selection of the low-throughput program (step S15). If the total current is less than the processing speed current threshold value Te (step S14: No), the tester command unit 64 commands selection of the high-throughput program (step S16).

Additionally, the first determination processing unit 65 determines whether the total current is greater than or equal to the start current threshold value Ta (step S17). If the total current is less than the start current threshold value Ta (step S17: No), the tester command unit 64 starts the testing of the unoperated unit 21B (step S18). If the total current is greater than or equal to the start current threshold value Ta (step S17: Yes), the tester command unit 64 waits for the start of the testing of the unoperated unit 21B (step S19).

In the wait state of the unoperated unit 21B, the first determination processing unit 65 determines whether the total current reaches a value less than the release current threshold value Tb (step S20). If the total current is greater than or equal to the release current threshold value Tb (step S20: No), the process returns to step S19 and the wait state is continued. If the total current reaches a value less than the release current threshold value Tb (step S20: Yes), the tester command unit 64 commands the start of the testing of the unoperated unit 21B (step S21). This allows the test device 10 to avoid an increase in the power of the entire test device 10 at the start of the testing of the unoperated unit 21B.

Additionally, the test progress adjusting unit 63 performs the processing flow illustrated in FIG. 12 in order to perform the determination process by the second determination processing unit 66 during the testing of the operating unit 21A. In the processing flow of FIG. 12, steps S31 and S32 perform substantially the same processing flow as steps S11 and S12.

Then, the second determination processing unit 66 continuously determines whether the total current is greater than or equal to the in-operation current threshold value Tc during the testing of the operating unit 21A (step S33). If the total current is less than the in-operation current threshold value Tc (step S33: No), the testing of the operating unit 21A is continued as is (step S34).

If the total current is greater than or equal to the in-operation current threshold value Tc (step S33: Yes), the tester command unit 64 commands the wait of the testing of the operating unit 21A (step S35). The test unit 21 that has received the test wait command suspends the test of the wafer W after finishing the test item being currently performed. This reduces the total current supplied to each test unit 21.

In the wait state of the operating unit 21A, the second determination processing unit 66 determines whether the total current reaches a value less than the restart current threshold value Td (step S36). If the total current is greater than or equal to the restart current threshold value Td (step S36: No), the process returns to step S35 and the wait state is continued. If the total current reaches a value less than the restart current threshold value Td (step S36: Yes), the tester command unit 64 commands the restart of the testing of the operating test unit that is waiting (step S37). This allows the operating unit 21A to restart the test from a test item after the test item that has been performed before the wait.

As described above, also with respect to the operating unit 21A, the test device 10 determines whether to continue or cause the testing of the operating unit 21A to be on standby and whether to restart the testing of the operating unit 21A based on the total current. As a result, the test device 10 can effectively suppress the power consumption during the testing of each test unit 21.

Here, the test system 1 (the test device 10) does not need to perform all of the determination processes (a) to (c) described above, and may perform at least one or two of (a) to (c). Therefore, the test progress adjusting unit 63 may be configured to include one or two units among the first determination processing unit 65, the second determination processing unit 66, and the third determination processing unit 67 in accordance with the determination process to be performed. For example, the test system 1 does not start the testing of the unoperated unit 21B when the total current is large by performing only the determination process (a), so that the power consumption of the entire test device 10 can be suppressed. Alternatively, for example, the test system 1 causes the testing of the operating unit 21A to be on standby when the total current is large by performing only the determination process (b), so that the power consumption of the entire test device 10 can be suppressed. Alternatively, the test system 1 causes the test unit 21 to operate with a low current when the total current is large by performing only the determination process (c), so that the power consumption of the entire test device 10 can be suppressed.

Then, in a case of the test system 1 in which the determination processes (a) and (b) are combined, the timing when the unoperated unit 21B consumes the power and the adjustment of the power consumption amount during the testing of the operating unit 21A can be appropriately adjusted. In a case of the test system 1 in which the determination processes (a) and (c) are combined, the timing when the unoperated unit 21B consumes the power and the power consumption amount thereof at the start of the unoperated unit 21B can be appropriately adjusted. In a case of the test system 1 in which the determination processes (b) and (c) are combined, the power consumption during the testing of the operating unit 21A can be further suppressed while the power consumption is appropriately adjusted at the start of the unoperated unit 21B.

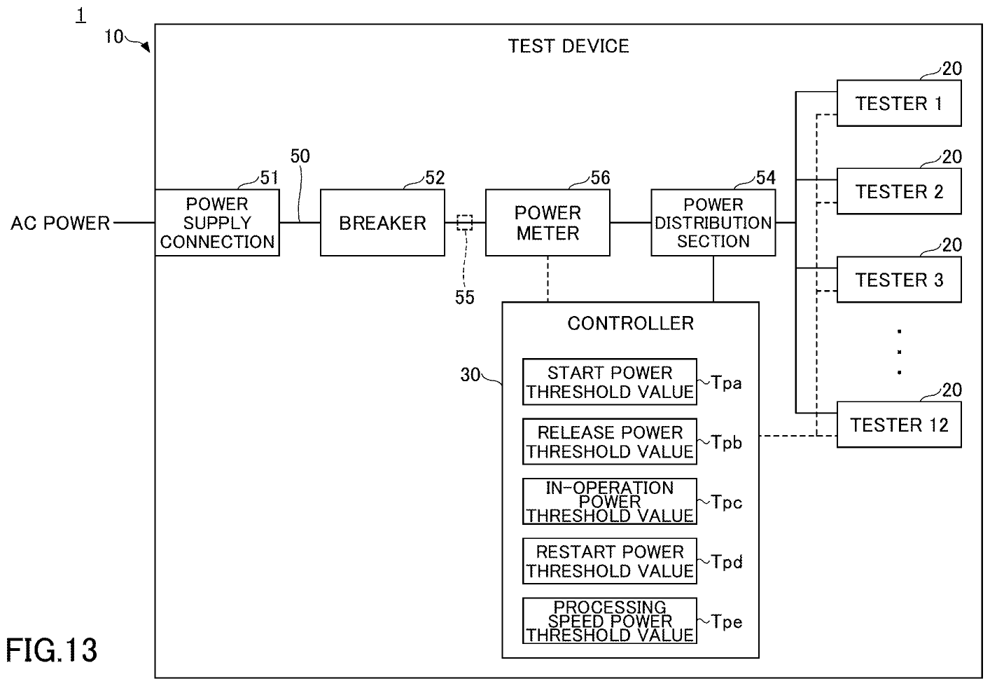

FIG. 13 is a block diagram illustrating an electrical connection and a communication connection of hardware of a test device 10 according to a modified example. As illustrated in FIG. 13, the test device 10 may apply a power meter 56 instead of the ammeter 53, detect total power, which is the sum of the power supplied to each tester 20 (test unit 21), and perform the determination processes (a) to (c) based on the total power. In this case, each current threshold value used for comparison with the total current is read as a power threshold value for comparison with the total power. That is, the controller 30 has a start power threshold value Tpa, a release power threshold value Tpb, an in-operation power threshold value Tpc, a restart power threshold value Tpd, and a processing speed power threshold value Tpe, and performs comparison with the total power supplied to the respective testers 20.

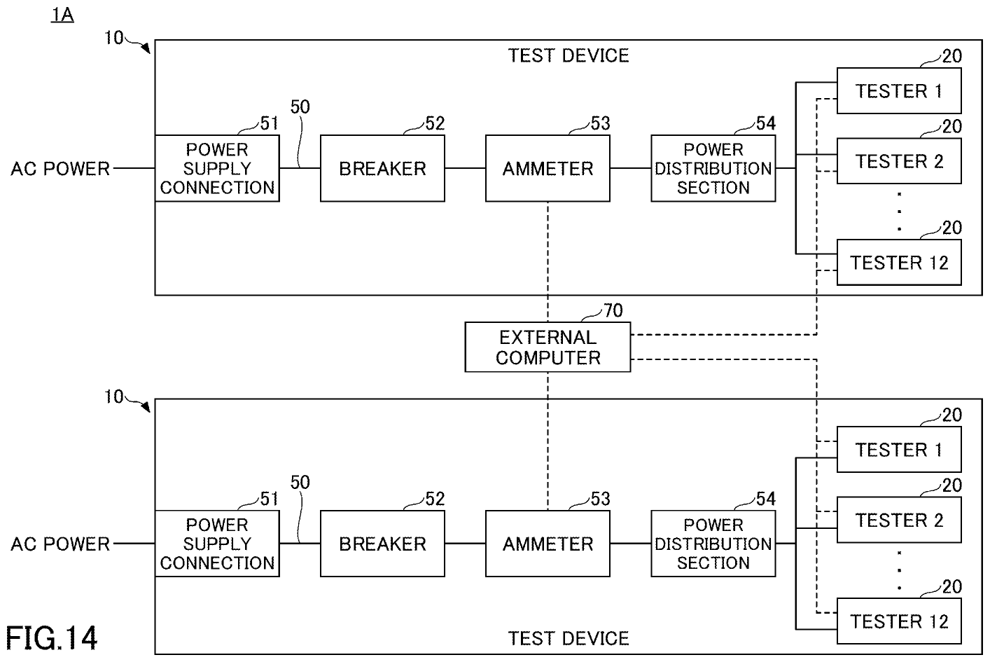

FIG. 14 is a block diagram illustrating a test system 1A according to another modified example. As illustrated in FIG. 14, the test system 1A may acquire the total current supplied to the respective test devices 10 (two test devices in FIG. 14) and perform the determination processes (a) to (c) described above based on the total current of the respective test devices 10 as a whole, in other words, the total current of the respective test devices 10 in a factory. In this case, to the controller for managing the progress of the test unit 21, the controller 30 (see FIG. 5) of the predetermined test device 10 may be applied, or an external computer 70 provided separately from each test device 10 and connected to each test device 10 may be applied.

As described above, the test method of the test system 1 according to the present disclosure monitors the total current or the total power supplied to the multiple test units 21 and appropriately adjusts the testing of the test units 21. This allows the test method to suppress the occurrence of surplus power consumption to suppress the power consumption of the test system 1 even in a configuration including the multiple test units 21. Therefore, the test system 1 can reduce a large distribution of the power supply capacity of the factory to the test system 1, thereby stably distributing the power supply capacity of the factory to other facilities.

Additionally, the test method performs all of the determination processing (a), the determination processing (b), and the determination processing (c). This allows the test method to manage the progress of the testing of the multiple test units 21 in more detail, so that the power consumption of the test system 1 can be suppressed while the test speed is secured.

Additionally, the current threshold values to be compared with the total current are set to satisfy the following relationship (1), or the power threshold values to be compared with the total power are set to satisfy the following relationship (2).

The processing speed current threshold value≤the start current threshold value<the in-operation current threshold value (1)

The processing speed power threshold value≤the start power threshold value<the in-operation power threshold value (2)

This allows the test method to satisfactorily wait for the start of the testing of the unoperated unit 21B based on the total current or the total power, and effectively suppress an increase in the power consumption of the test system 1.

Additionally, the current threshold value to be compared with the total current or the power threshold value to be compared with the total power can be set in response to a user operation. This allows the test method to cause the testing of each test unit 21 to proceed with the power according to a user's request.

Additionally, in the wait of the testing of the unoperated unit 21B by the determination process (a), the test method continues the wait of the unoperated unit 21B when the total current is greater than or equal to the release current threshold value Tb or the total power is greater than or equal to the release power threshold value Tpb, the test method starts the testing of the unoperated unit 21B when the total current reaches a value less than the release current threshold value Tb or the total power reaches a value less than the release power threshold value Tpb, and the release current threshold value Tb is set to be less than or equal to the start current threshold value Ta or the release power threshold value Tpb is set to be less than or equal to the start power threshold value Tpa. This allows the test method to start the testing of the unoperated unit 21B at the timing when the total current or the total power decreases when causing the testing of the unoperated unit 21B to be on standby.

Additionally, in the wait of the testing of the operating unit 21A by the determination process (b), the test method continues the wait of the operating unit 21A when the total current is greater than or equal to the restart current threshold value Td or the total power is greater than or equal to the restart power threshold value Tpd, the test method restarts the testing of the operating unit 21A when the total current reaches a value less than the restart current threshold value Td or the total power reaches a value less than the restart power threshold value Tpd, and the restart current threshold value Td is set to be less than or equal to the in-operation current threshold value Tc or the restart power threshold value Tpd is set to be less than or equal to the in-operation power threshold value Tpc. This allows the test method to start the testing of the operating unit 21A at the timing when the total current or the total power decreases when causing the testing of the operating unit 21A to be on standby.

Additionally, in the wait of the testing of the operating unit 21A by the determination process (b), the test method continues the test until the test item being already performed in the operating unit 21A is finished, and waits for performing the next test item. With this, the test system 1 does not need to perform the test item that has been previously performed again after the restart of the testing of the operating unit 21A, thereby suppressing a decrease in the test speed of the operating unit 21A.

Additionally, the multiple test units 21 include the low-throughput program for testing with a low-power and low-speed processing content and the high-throughput program for testing with a high-power and high-speed processing content, and the unoperated unit 21B executes either the low-throughput program or the high-throughput program by the determination process (c). This allows the test system 1 to appropriately adjust the test speed of the test unit 21 in accordance with the total current or the total power.

Additionally, the test unit 21 includes the tester 20 and the probe card PR that is mounted on the tester 20 and that comes into contact with the substrate (the wafer W), which is an object to be tested, and tests electrical characteristics of the semiconductor device formed on the substrate. This allows the test system 1 to perform the electrical test of the substrate while suppressing the power consumption.

Additionally, one embodiment of the present disclosure is the test system 1 including multiple test units 21, each of which is configured to perform the electrical test on an object to be tested (the wafer W), and includes at least one of the ammeter 53 configured to detect the total current, which is the sum of the current supplied to each of the multiple test units 21 and the power meter 56 configured to detect the total power, which is the sum of the power, and the controller (the controller 30 or the external computer 70) configured to perform at least one of the following determination processes (a) to (c) based on the detected total current or total power.

(a) Compare the total current with the start current threshold value Ta or compare the total power with the start power threshold value Tpa at the timing when the unoperated unit 21B that is not performing the test among the multiple test units 21, starts the testing, wait for the start of the testing of the unoperated unit 21B when the total current is greater than or equal to the start current threshold value Ta or the total power is greater than or equal to the start power threshold value Tpa as a result of the comparison, and start the testing of the unoperated unit 21B when the total current is less than the start current threshold value Ta or the total power is less than the start power threshold value Tpa.

(b) Compare the total current with the in-operation current threshold value Tc or compare the total power with the in-operation power threshold value Tpc during the testing of the operating unit 21A performing the test among the multiple test units 21, causing at least one of the operating units 21A to wait when the total current is greater than or equal to the in-operation current threshold value Tc or the total power is greater than or equal to the in-operation power threshold value Tpc as a result of the comparison, and continue the testing of the operating unit 21A when the total current is less than the in-operation current threshold value Tc or the total power is less than the in-operation power threshold value Tpc.

(c) Compare the total current with the processing speed current threshold value Te or compare the total power with the processing speed power threshold value Tpe at the timing when the unoperated unit 21B starts the testing, and set the low-power and low-speed processing content to start the testing of the unoperated unit 21B when the total current is greater than or equal to the processing speed current threshold value Te or the total power is greater than or equal to the processing speed power threshold value Tpe as a result of the comparison, and set the high-power and high-speed processing content to start the testing of the unoperated unit 21B when the total current is less than the processing speed current threshold value Te or the total power is less than the processing speed power threshold value Tpe.

This allows the test system 1 to suppress the power consumption of the test system 1 even in a configuration including multiple test units 21.

The test methods of the test systems 1 and 1A, and the test systems 1 and 1A according to the embodiments disclosed herein are illustrative in all respects and are not restrictive. The embodiments can be modified and improved in various forms without departing from the scope and spirit of the appended claims. The matters described in the multiple embodiments can also take other configurations as long as there is no contradiction, and can be combined as long as there is no contradiction. For example, an object to be tested by the test system 1 is not limited to a substrate (a wafer W), but may be various electrical and electronic devices that require an electrical test.

This application is based upon and claims the priority to Japanese Patent Application No. 2021-124355 filed on Jul. 29, 2021, the entire contents of which are incorporated herein by reference.

### DESCRIPTION OF REFERENCE SYMBOLS

1, 1A test system
10 test device
20 tester
21A operating unit
21B unoperated unit
30 controller
53 ammeter
56 power meter
70 external computer
Ta start current threshold value
Tb release current threshold value
Tc in-operation current threshold value
Td restart current threshold value
Te processing speed current threshold value
Tpa start power threshold value
Tpb release power threshold value
Tpc in-operation power threshold value
Tpd restart power threshold value
Tpe processing speed power threshold value

1. A test method of a test system including a plurality of test units, each of which is configured to perform an electrical test of an object to be tested, the test method comprising:
detecting a total current that is a sum of a current supplied to each of the plurality of test units or a total power that is a sum of a power supplied to each of the plurality of test units; and
performing at least one of following determination processes (a) to (c) based on the total current or the total power that is detected, an operating unit being a test unit that is performing testing among the plurality of test units, and an unoperated unit being a test unit that are not performing testing among the plurality of test units,
the determination process (a): compare the total current with a start current threshold value or compare the total power with a start power threshold value at a timing when the unoperated unit starts the testing; wait for a start of the testing of the unoperated unit when the total current is greater than or equal to the start current threshold value or the total power is greater than or equal to the start power threshold value as a result of the comparison; and start the testing of the unoperated unit when the total current is less than the start current threshold value or the total power is less than the start power threshold value,
the determination process (b): compare the total current with an in-operation current threshold value or compare the total power with an in-operation power threshold value during the testing of the operating unit; cause the operating unit to wait when the total current is greater than or equal to the in-operation current threshold value or the total power is greater than or equal to the in-operation power threshold value as a result of the comparison; and continue the testing of the operating unit when the total current is less than the in-operation current threshold value or the total power is less than the in-operation power threshold value, and
the determination process (c): compare the total current with a processing speed current threshold value or compare the total power with a processing speed power threshold value at a timing when the unoperated unit starts testing; set a low-power and low-speed processing content to start the testing of the unoperated unit when the total current is greater than or equal to the processing speed current threshold value or the total power is greater than or equal to the processing speed power threshold value as a result of the comparison; and set a high-power and high-speed processing content to start the testing of the unoperated unit when the total current is less than the processing speed current threshold value or the total power is less than the processing speed power threshold value.

2. The test method of the test system as claimed in claim 1, wherein all of the determination process (a), the determination process (b), and the determination process (c) are performed.

3. The test method of the test system as claimed in claim 2, wherein the current threshold values to be compared with the total current are set to satisfy a following relationship (1), or the power threshold values to be compared with the total power are set to satisfy a following relationship (2),
the processing speed current threshold value≤the start current threshold value<the in-operation current threshold value (1)
the processing speed power threshold value≤the start power threshold value<the in-operation power threshold value (2).

4. The test method of the test system as claimed in claim 1, wherein the current threshold values to be compared with the total current or the power threshold values to be compared with the total power are configurable in response to an operation of a user.

5. The test method of the test system as claimed in claim 1, wherein in the waiting of the testing of the unoperated unit by the determination process (a),
the wait of the unoperated unit is continued when the total current is greater than or equal to a release current threshold value or the total power is greater than or equal to a release power threshold value,
the testing of the unoperated unit is started when the total current is less than the release current threshold value or the total power is less than the release power threshold value, and
the release current threshold value is set to be less than or equal to the start current threshold value, or the release power threshold value is set to be less than or equal to the start power threshold value.

6. The test method of the test system as claimed in claim 1, wherein in the waiting of the testing of the operating unit by the determination processing (b),
the wait of the operating unit is continued when the total current is greater than or equal to a restart current threshold value or the total power is greater than or equal to a restart power threshold value, and
the testing of the operating unit is restarted when the total current reaches a value less than the restart current threshold value or the total power reaches a value less than the restart power threshold value; and
the restart current threshold value is set to be less than or equal to the in-operation current threshold value, or the restart power threshold value is set to be less than or equal to the in-operation power threshold value.

7. The test method of the test system as claimed in claim 1, wherein in the waiting of the testing of the operating unit by the determination processing (b), the test is continued until a test item being already performed in the operating unit is finished, and performing of the next test item is on standby.

8. The test method of the test system as claimed in claim 1,
wherein the plurality of test units include a low-throughput program for performing the test with the low-power and low-speed processing content and a high-throughput program for performing the test with the high-power and high-speed processing content, and
wherein the unoperated unit executes either the low-throughput program or the high-throughput program by the determination processing (c).

9. The test method of the test system as claimed in claim 1,
wherein the test unit includes a tester and a probe card that is mounted on the tester and that comes into contact with a substrate being the object to be tested, and tests electrical characteristics of a semiconductor device formed on the substrate.

10. A test system comprising:
a plurality of test units, each of which is configured to perform an electrical test of an object to be tested,
at least one of an ammeter configured to detect a total current that is a sum of a current supplied to each of the plurality of test units and a power meter configured to detect a total power that is a sum of a power supplied to each of the plurality of test units; and
a controller configured to perform at least one of following determination processes (a) to (c) based on the total current or the total power that is detected, an operating unit being a test unit that is performing testing among the plurality of test units, and an unoperated unit being a test unit that are not performing testing among the plurality of test units,
the determination process (a): compare the total current with a start current threshold value or compare the total power with a start power threshold value at a timing when the unoperated unit starts the testing; wait for a start of the testing of the unoperated unit when the total current is greater than or equal to the start current threshold value or the total power is greater than or equal to the start power threshold value as a result of the comparison; and start the testing of the unoperated unit when the total current is less than the start current threshold value or the total power is less than the start power threshold value,
the determination process (b): compare the total current with an in-operation current threshold value or compare the total power with an in-operation power threshold value during the testing of the operating unit; cause the operating unit to wait when the total current is greater than or equal to the in-operation current threshold value or the total power is greater than or equal to the in-operation power threshold value as a result of the comparison; and continue the testing of the operating unit when the total current is less than the in-operation current threshold value or the total power is less than the in-operation power threshold value, and
the determination process (c): compare the total current with a processing speed current threshold value or compare the total power with a processing speed power threshold value at a timing when the unoperated unit starts testing; and set a low-power and low-speed processing content to start the testing of the unoperated unit when the total current is greater than or equal to the processing speed current threshold value or the total power is greater than or equal to the processing speed power threshold value as a result of the comparison; and set a high-power and high-speed processing content to start the testing of the unoperated unit when the total current is less than the processing speed current threshold value or the total power is less than the processing speed power threshold value.
